(19) United States
(12) Patent Application Publication
(10) Pub. No.: US 2024/0421646 A1
(43) Pub. Date: Dec. 19, 2024

(54) COIL SUBSTRATE, MOTOR COIL SUBSTRATE, AND MOTOR

(71) Applicant: IBIDEN CO., LTD., Ogaki (JP)

(72) Inventors: Takahisa HIRASAWA, Ogaki (JP); Takayuki FURUNO, Ogaki (JP)

(73) Assignee: IBIDEN CO., LTD., Ogaki (JP)

(21) Appl. No.: 18/819,323

(22) Filed: Aug. 29, 2024

Related U.S. Application Data
(63) Continuation of application No. PCT/JP2023/006880, filed on Feb. 24, 2023.

(30) Foreign Application Priority Data
Mar. 4, 2022 (JP) 2022-033055

(51) Int. Cl. H02K 3/04; H02K 5/22; H02K 7/00

(52) U.S. Cl. CPC H02K 3/04; H02K 5/225; H02K 7/003

(57) ABSTRACT

A coil substrate includes a flexible substrate, terminals formed on one side of the flexible substrate such that the terminals are positioned in a longitudinal direction of the flexible substrate, coils each comprising a first wiring formed on a first surface and a second wiring formed on a second surface on the opposite side with respect to the first surface, and connection wirings formed on the flexible substrate such that the connection wirings include wirings connecting the terminals and the coils respectively and wirings connecting two of the coils respectively and that the connection wirings extend obliquely with respect to the longitudinal direction of the flexible substrate. The coil substrate is wound along the longitudinal direction of the flexible substrate around an axis extending in an orthogonal direction orthogonal to the longitudinal direction such that the coil substrate is formed into a cylindrical shape.

### CROSS-REFERENCE TO RELATED APPLICATIONS

The present application is a continuation of and claims the benefit of priority to International Application No. PCT/JP2023/006880, filed Feb. 24, 2023, which is based upon and claims the benefit of priority to Japanese Application No. 2022-033055, filed Mar. 4, 2022. The entire contents of these applications are incorporated herein by reference.

### BACKGROUND OF THE INVENTION

### Field of the Invention

The present invention relates to a coil substrate, a motor coil substrate formed using the coil substrate, and a motor formed using the motor coil substrate.

### Description of Background Art

Japanese Patent Application Laid-Open Publication No. 2021-48718 describes a coil substrate having a flexible substrate and coils formed on the flexible substrate. The entire contents of this publication are incorporated herein by reference.

### SUMMARY OF THE INVENTION

According to one aspect of the present invention, a coil substrate includes a flexible substrate, terminals formed on one side of the flexible substrate such that the terminals are positioned in a longitudinal direction of the flexible substrate, coils each comprising a first wiring formed on a first surface and a second wiring formed on a second surface on the opposite side with respect to the first surface, and connection wirings formed on the flexible substrate such that the connection wirings include wirings connecting the terminals and the coils respectively and wirings connecting two of the coils respectively and that the connection wirings extend obliquely with respect to the longitudinal direction of the flexible substrate. The coil substrate is wound along the longitudinal direction of the flexible substrate around an axis extending in an orthogonal direction orthogonal to the longitudinal direction such that the coil substrate is formed into a cylindrical shape.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view schematically illustrating a coil substrate according to an embodiment of the present invention;

FIG. 2 is a cross-sectional view schematically illustrating a coil substrate according to an embodiment of the present invention;

FIG. 3 is a plan view schematically illustrating a U phase in a coil substrate according to an embodiment of the present invention;

FIG. 4 is a plan view schematically illustrating a V phase in a coil substrate according to an embodiment of the present invention;

FIG. 5 is a plan view schematically illustrating a W phase in a coil substrate according to an embodiment of the present invention;

FIG. 6 is a plan view comparing the U phase, V phase, and W phase of a coil substrate according to an embodiment of the present invention;

FIG. 7 is an enlarged explanatory diagram schematically illustrating a part of a coil substrate according to an embodiment of the present invention;

FIG. 8 is a perspective view schematically illustrating a motor coil substrate according to an embodiment of the present invention;

FIG. 9 is a cross-sectional view schematically illustrating a motor according to an embodiment of the present invention;

FIG. 10 is a plan view schematically illustrating a coil substrate of a first modified example according to an embodiment of the present invention;

FIG. 11 is a plan view schematically illustrating a U phase in the coil substrate of the first modified example according to an embodiment of the present invention;

FIG. 12 is a plan view schematically illustrating a V phase in the coil substrate of the first modified example according to an embodiment of the present invention;

FIG. 13 is a plan view schematically illustrating a W phase in the coil substrate of the first modified example according to an embodiment of the present invention;

FIG. 14 is a plan view comparing the U phase, V phase, and W phase of the coil substrate of the first modified example according to an embodiment of the present invention;

FIG. 15 is a plan view schematically illustrating a coil substrate of a second modified example according to an embodiment of the present invention;

FIG. 16 is a plan view schematically illustrating a U phase in the coil substrate of the second modified example according to an embodiment of the present invention;

FIG. 17 is a plan view schematically illustrating a V phase in the coil substrate of the second modified example according to an embodiment of the present invention;

FIG. 18 is a plan view schematically illustrating a W phase in the coil substrate of the second modified example according to an embodiment of the present invention; and

FIG. 19 is a plan view comparing the U phase, V phase, and W phase of the coil substrate of the second modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### EMBODIMENT

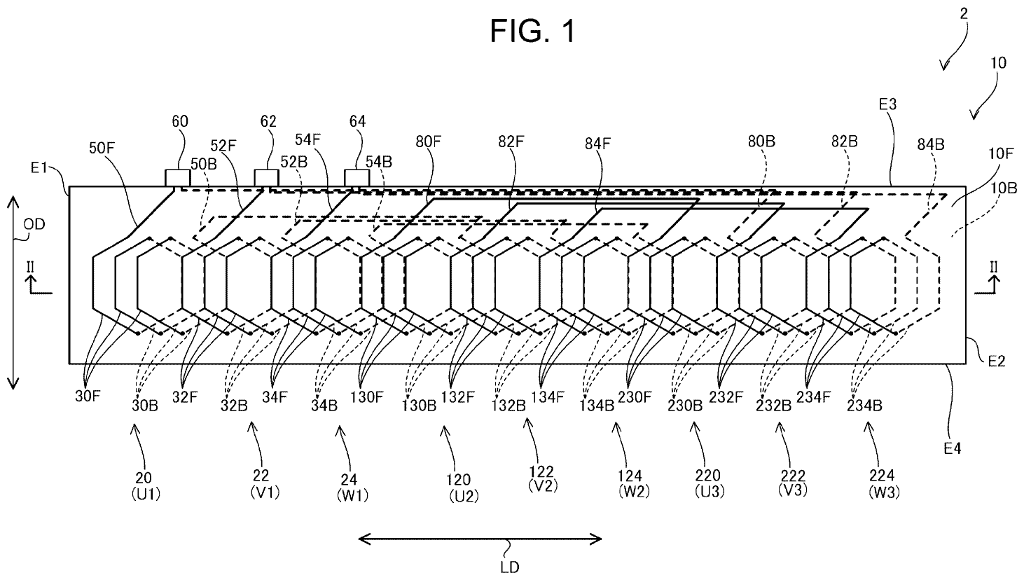

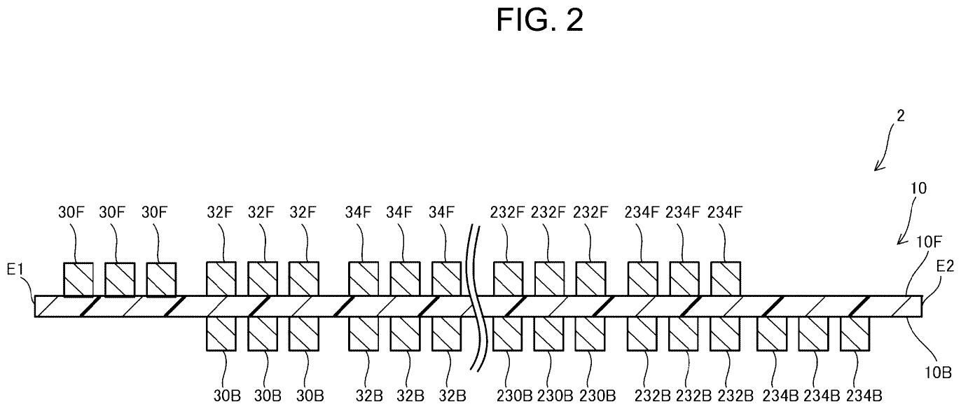

FIG. 1 is a plan view illustrating a coil substrate 2 of an embodiment. FIG. 2 is a cross-sectional view between II-II of FIG. 1. As illustrated in FIG. 1, the coil substrate 2 has a flexible substrate 10, nine coils (20, 22, 24, 120, 122, 124, 220, 222, 224), three terminals (60, 62, 64), and connection wirings (50F, 50B, 52F, 52B, 54F, 54B, 80F, 80B, 82F, 82B, 84F, 84B).

The flexible substrate 10 is a resin substrate having a first surface (10F) and a second surface (10B) on the opposite side with respect to the first surface (10F). The flexible substrate 10 is formed using an insulating resin such as polyimide or polyamide. The flexible substrate 10 is flexible. The flexible substrate 10 is formed in a rectangular shape having four sides, first side (E1)-fourth side (E4). The first side (E1) is a short side on one end side of the flexible substrate 10 in a longitudinal direction (arrow (LD) direction in FIG. 1). The second side (E2) is a short side on the other end side in the longitudinal direction. The first side (E1) and the second side (E2) are short sides extending along an orthogonal direction (arrow (OD) direction in FIG. 1) that is orthogonal to the longitudinal direction. The third side (E3) and the fourth side (E4) are long sides extending in the longitudinal direction. When the coil substrate 2 is wound into a cylindrical shape to form a motor coil substrate 550 (see FIG. 8), the first surface (10F) is positioned on an inner circumferential side and the second surface (10B) is positioned on an outer circumferential side.

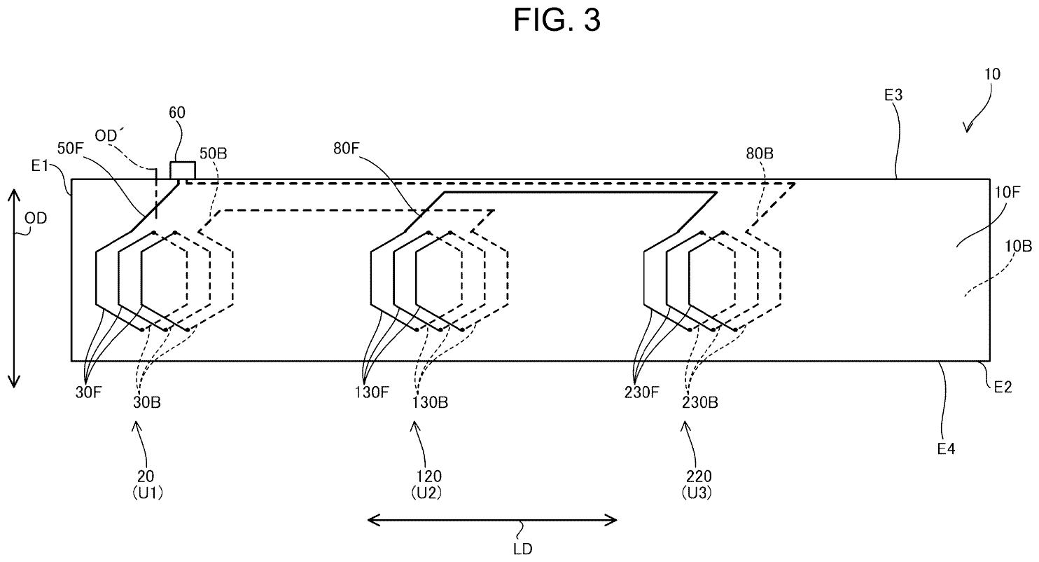

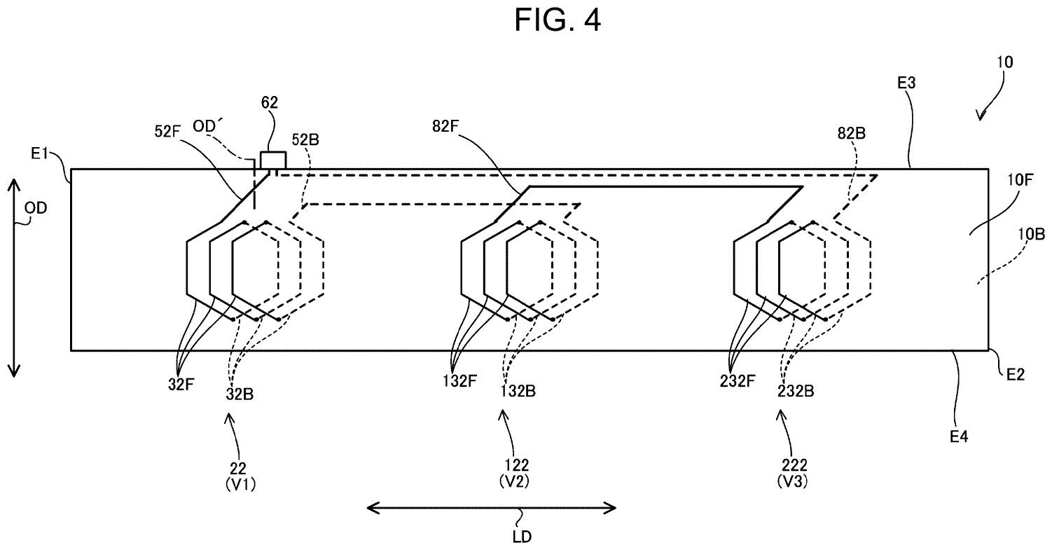

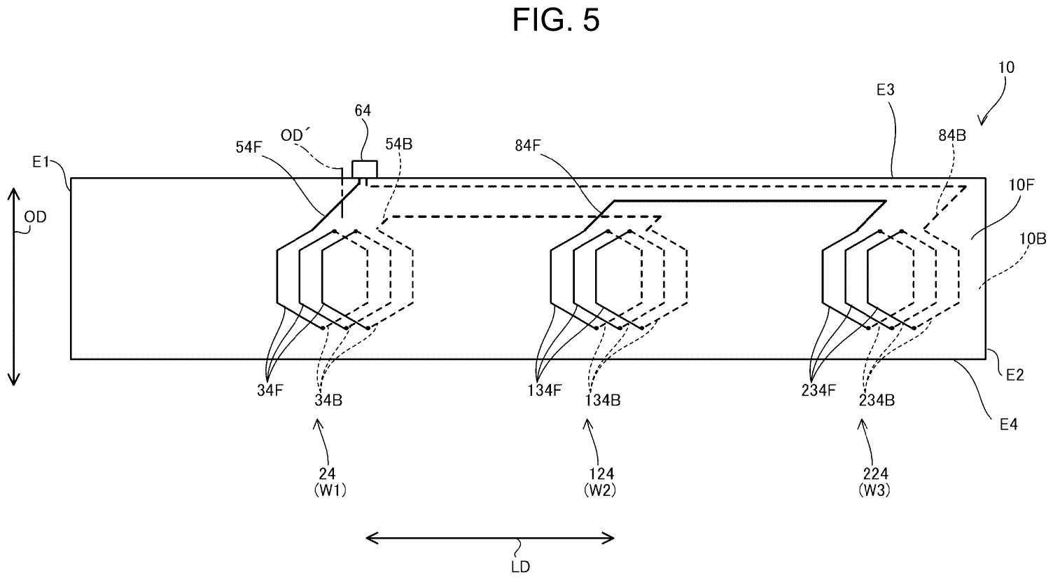

The three terminals (60, 62, 64) are formed along the longitudinal direction on the third side (E3) of the flexible substrate 10 with spaces between them. As illustrated in FIG. 3, the coils (20, 120, 220) are connected to the terminal 60 via the connection wirings (50F, 50B, 80F, 80B). As illustrated in FIG. 4, the coils (22, 122, 222) are connected to the terminal 62 via the connection wirings (52F, 52B, 82F, 82B). As illustrated in FIG. 5, the coils (24, 124, 224) are connected to the terminal 64 via the connection wirings (54F, 54B, 84F, 84B).

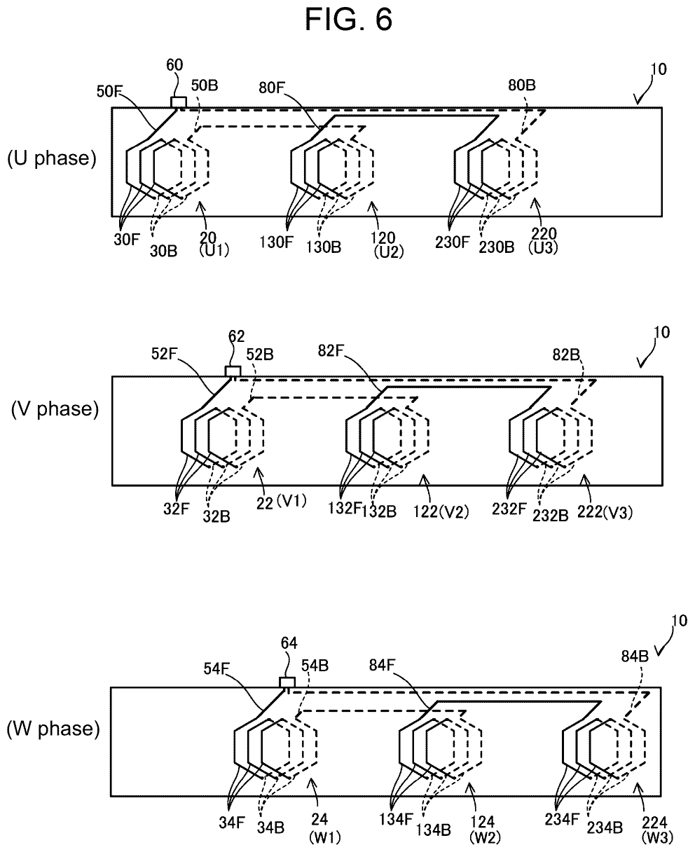

As illustrated in FIG. 1, the nine coils (20, 22, 24, 120, 122, 124, 220, 222, 224) are formed along the longitudinal direction of flexible substrate 10. The nine coils (20, 22, 24, 120, 122, 124, 220, 222, 224) are formed in this order from the first side (E1) to the second side (E2). As illustrated in FIGS. 3 and 6, the coils (20 (U1), 120 (U2), 220 (U3)) form a U phase. As illustrated in FIGS. 4 and 6, the coils (22 (V1), 122 (V2), 222 (V3)) form a V phase. As illustrated in FIGS. 5 and 6, the coils (24 (W1), 124 (W2), 224 (W3)) form a W phase. As illustrated in FIG. 6, the U phase, V phase, and W phase are formed offset along the longitudinal direction. The nine coils (20, 22, 24, 120, 122, 124, 220, 222, 224) are formed in the order of the U phase, V phase, and W phase along the longitudinal direction. The U phase, V phase, and W phase of a three-phase motor may be formed in forms other than this.

As illustrated in FIGS. 1 and 3, the coil 20 is formed by that a first wiring (30F) forming a half turn of one turn is formed on the first surface (10F) side, a second wiring (30B) forming the remaining half turn is formed on the second surface (10B) side, and adjacent turns are formed in a staggered manner. In FIG. 1, the coil 20 has wirings for three turns. The first wirings (30F) and second wirings (30B) forming the turns are electrically connected via via conductors penetrating the flexible substrate 10. The first wirings (30F) each have an orthogonal part extending along the orthogonal direction (see the arrow (OD)). The second wirings (30B) also each have an orthogonal part extending along the orthogonal direction.

Similarly, as illustrated in FIGS. 1 and 4, the coil 22 is formed by that a first wiring (32F) forming a half turn of one turn is formed on the first surface (10F) side, a second wiring (32B) forming the remaining half turn is formed on the second surface (10B) side, and adjacent turns are formed in a staggered manner. The coil 22 has wirings for three turns. The first wirings (32F) and second wirings (32B) forming the turns are electrically connected via via conductors. The first wirings (32F) each have an orthogonal part extending along the orthogonal direction (see the arrow (OD)). The second wirings (32B) also each have an orthogonal part extending along the orthogonal direction.

As illustrated in FIGS. 1 and 5, the coil 24 is formed by that a first wiring (34F) forming a half turn of one turn is formed on the first surface (10F) side, a second wiring (34B) forming the remaining half turn is formed on the second surface (10B) side, and adjacent turns are formed in a staggered manner. The coil 24 has wirings for three turns.

The first wirings (34F) and second wirings (34B) forming the turns are electrically connected via via conductors. The first wirings (34F) each have an orthogonal part extending along the orthogonal direction (see the arrow (OD)). The second wirings (34B) also each have an orthogonal part extending along the orthogonal direction.

The coils (120, 122, 124, 220, 222, 224) also have similar structures to the coils (20, 22, 24). That is, the coils (120, 122, 124) also each have first wirings (130F, 132F, 134F) and second wirings (130B, 132B, 134B) for three turns. The coils (220, 222, 224) also each have first wirings (230F, 232F, 234F) and second wirings (230B, 232B, 234B) for three turns.

As illustrated in FIGS. 1 and 2, the orthogonal parts (portions extending along the orthogonal direction (OD); the same applies hereinafter) of the second wirings (30B) of the coil 20 overlap with the orthogonal parts of the first wirings (32F) of the adjacent coil 22 via the flexible substrate 10. The orthogonal parts of the second wirings (32B) of the coil 22 overlap with the orthogonal parts of the first wirings (34F) of the adjacent coil 24 via the flexible substrate 10.

Similarly, the orthogonal parts of the second wirings (34B) OF the coil 24 overlap with the orthogonal parts of the first wirings (130F) OF the adjacent coil 120. The orthogonal parts of the second wirings (130B) of the coil 120 overlap with the orthogonal parts of the first wirings (132F) of the adjacent coil 122. The orthogonal parts of the second wirings (132B) of the coil 122 overlap with the orthogonal parts of the first wirings (134F) of the adjacent coil 124. The orthogonal parts of the second wirings (134B) of the coil 124 overlap with the orthogonal parts of the first wirings (230F) of the adjacent coil 220. The orthogonal parts of the second wirings (230B) of the coil 220 overlap with the orthogonal parts of the first wirings (232F) of the adjacent coil 222. The orthogonal parts of the second wirings (232B) of the coil 222 overlap with the orthogonal parts of the first wirings (234F) of the adjacent coil 224.

The arrangement of the coils illustrated in FIGS. 1 and 2 is merely an example. In other modified examples, it is also possible that the orthogonal parts of the second wirings (30B) of the coil 20 do not overlap with the orthogonal parts of the first wirings (32F) of the immediately adjacent coil 22 as long as they overlap with the orthogonal parts of the first wirings of another coil (for example, the orthogonal parts of the first wirings (130F) of the third adjacent coil 120). Similarly, it is also possible that the orthogonal parts of the second wiring (32B) of the coil 22 also do not overlap with the orthogonal parts of the first wirings (34F) of the immediately adjacent coil 24 as long as they overlap with the orthogonal parts of the first wirings of another coil (for example, the orthogonal parts of the first wirings (132F) of the third adjacent coil 122).

As illustrated in FIGS. 1 and 3-6, the connection wirings (50F, 52F, 54F, 80F, 82F, 84F) are formed on the first surface (10F) side. The connection wirings (50B, 52B, 54B, 80B, 82B, 84B) are formed on the second surface (10B) side.

As illustrated in FIGS. 3 and 6, the connection wiring (50F) connects an end part of a first wiring (30F), which is one end of the coil 20, and the terminal 60. The connection wiring (50B) connects an end part of a second wiring (30B), which is the other end of the coil 20, and an end part of a second wiring (130B), which is one end of the coil 120. The connection wiring (80F) connects an end part of a first wiring (130F), which is the other end of the coil 120, and an end part of a first wiring (230F), which is one end of the coil 220. The connection wiring (80B) connects an end part of a second wiring (230B), which is the other end of the coil 220, and the terminal 60. That is, the coils (20, 120, 220) that form the U phase are connected in series via the connection wirings (50F, 50B, 80F, 80B) and the terminal 60.

As illustrated in FIGS. 4 and 6, the connection wiring (52F) connects an end part of a first wiring (32F), which is one end of the coil 22, and the terminal 62. The connection wiring (52B) connects an end part of a second wiring (32B), which is the other end of the coil 22, and an end part of a second wiring (132B), which is one end of the coil 122. The connection wiring (82F) connects an end part of a first wiring (132F), which is the other end of the coil 122, and an end part of a first wiring (232F), which is one end of the coil 222. The connection wiring (82B) connects an end part of a second wiring (232B), which is the other end of the coil 222, and the terminal 62. The coils (22, 122, 222) that form the V phase are connected in series via the connection wirings (52F, 52B, 82F, 82B) and the terminal 62.

As illustrated in FIGS. 5 and 6, the connection wiring (54F) connects an end part of a first wiring (34F), which is one end of the coil 24, and the terminal 64. The connection wiring (54B) connects an end part of a second wiring (34B), which is the other end of the coil 24, and an end part of a second wiring (134B), which is one end of the coil 124. The connection wiring (84F) connects an end part of a first wiring (134F), which is the other end of the coil 124, and an end part of a first wiring (234F), which is one end of the coil 224. The connection wiring (84B) connects an end part of a second wiring (234B), which is the other end of the coil 224, and the terminal 64. The coils (24, 124, 224) that form the W phase are connected in series via the connection wirings (54F, 54B, 84F, 84B) and the terminal 64.

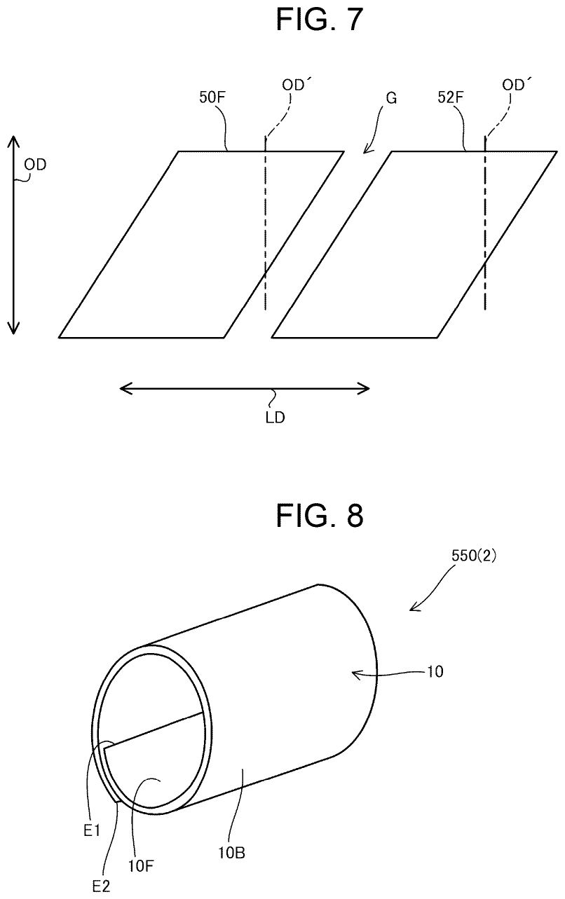

As illustrated in FIGS. 1 and 3-6, the connection wirings (50F, 52F, 54F, 80F, 82F, 84F) formed on the first surface (10F) side extend obliquely (are inclined) with respect to the longitudinal direction (the arrow (LD) direction in FIG. 1). Substantially none of the connection wirings (50F, 52F, 54F, 80F, 82F, 84F) have a portion that extends in the orthogonal direction (the arrow (OD) direction). The connection wirings (50F, 52F, 54F, 80F, 82F, 84F) extend obliquely (are inclined) also with respect to the orthogonal direction. FIG. 7 is an enlarged explanatory diagram schematically illustrating a connection wiring (50F) and a connection wiring (52F) that are formed adjacent to each other on the first surface (10F) side. As illustrated in FIG. 7, the connection wiring (50F) and the connection wiring (52F) are both wide wirings. In the example of FIG. 7, the connection wiring (50F) and the connection wiring (52F) are formed in parallel. The connection wiring (50F) and the connection wiring (52F) are inclined with respect to both the longitudinal direction and the orthogonal direction. Further, a gap (G) formed between the connection wiring (50F) and the connection wiring (52F) also is inclined with respect to both the longitudinal direction and the orthogonal direction. The connection wiring (50F) and the connection wiring (52F) are both inclined, for example, at +5 degrees or more or −5 degrees or more with respect to a virtual line (OD′) parallel to the orthogonal direction, in terms of an inner angle between the virtual line (OD′) and the connection wirings (50F, 52F). Since the connection wirings (50F, 52F) are inclined at +5 degrees or more or −5 degrees or more with respect to the virtual line (OD′), when the coil substrate 2 is wound, it is formed into a cylindrical shape instead of a polygonal cylindrical shape with a polygonal cross section. Further, the connection wirings (50F, 52F) are desirably inclined at +10 to +45 degrees with respect to the virtual line (OD′) in terms of the inner angle. Further, the connection wirings (50F, 52F) are desirably inclined at −10 to −45 degrees with respect to the virtual line (OD′). When the coil substrate 2 is wound in which the connection wirings (50F, 52F) are inclined at +10 to +45 degrees with respect to the virtual line (OD′), or inclined at −10 to −45 degrees with respect to the virtual line (OD′), it is formed into a cylindrical shape instead of a polygonal cylindrical shape with a polygonal cross section. Further, rewinding due to winding misalignment that occurs when the winding is completed also is suppressed. As a result, a motor coil substrate obtained by winding the coil substrate 2 can be formed into a cylindrical shape with a circular cross section. The inclination of the connection wirings (50F, 52F) is measured using a protractor based on an image captured from a front side of the wirings. In the embodiment, the connection wirings (50F, 52F) are inclined at +30 degrees with respect to the virtual line (OD′). The inner angle in FIG. 7 is an inclination of a “+” direction when an intersection of the virtual line (OD′) and the connection wirings (50F, 52F) is inclined to an upper right side of the virtual line, and conversely, an inclination of a “−” direction when the intersection is inclined to an upper left side of the virtual line (OD′). In FIG. 7, only the adjacent connection wiring (50F) and connection wiring (52F) are illustrated as examples. Although not illustrated in FIG. 7, the connection wiring (52F) and connection wiring (54F), the connection wiring (80F) and connection wiring (82F), and the connection wiring (82F) and connection wiring (84F) also each have a similar relationship. As illustrated in FIGS. 3-5, the connection wirings (54F, 80F, 82F, 84F) also are inclined at a similar angle to the connection wirings (50F, 52F).

As illustrated in FIGS. 1 and 3-6, the connection wirings (50B, 52B, 54B, 80B, 82B, 84B) formed on the second surface (10B) side also extend obliquely (are inclined) with respect to the longitudinal direction (the arrow (LD) direction). Also substantially none of the connection wirings (50B, 52B, 54B, 80B, 82B, 84B) have a portion that extends in the orthogonal direction (the arrow (OD) direction). The connection wirings (50B, 52B, 54B, 80B, 82B, 84B) extend obliquely (are inclined) also with respect to the orthogonal direction. As illustrated in FIGS. 3-5, the connection wirings (50B, 52B, 54B, 80B, 82B, 84B) are inclined, for example, at +5 degrees or more or −5 degrees or more with respect to a virtual line (OD′) parallel to the orthogonal direction, in terms of an inner angle between the virtual line (OD′) and the connection wirings (50B, 52B, 54B, 80B, 82B, 84B). Further, the connection wirings (50B, 52B, 54B, 80B, 82B, 84B) are desirably inclined at +10 to +45 degrees with respect to the virtual line (OD′) in terms of the inner angle. As a result, a motor coil substrate obtained by winding the coil substrate can be formed into a cylindrical shape with a circular cross section. Gaps formed respectively between the connection wiring (50B) and the connection wiring (52B), between the connection wiring (52B) and the connection wiring (54B), between the connection wiring (54B) and the connection wiring (80B), between the connection wiring (80B) and the connection wiring (82B), and between the connection wiring (82B) and the connection wiring (84B) also extend obliquely with respect to the longitudinal direction. Further, the inner angle in the drawings is an inclination of a “+” direction when an intersection of the virtual line (OD′) and the connection wirings (50B, 52B, 54B, 80B, 82B, 84B) is inclined to an upper right side of the virtual line, and conversely, an inclination of a “−” direction when the intersection is inclined to an upper left side of the virtual line (OD′).

The connection wirings that connect the coils and the terminals include the connection wirings (50F, 52F, 54F, 80F, 82F, 84F) formed on the first surface (10F) side and the connection wirings (50B, 52B, 54B, 80B, 82B, 84B) formed on the second surface (10B) side. When viewed from the first surface (10F) side of the flexible substrate 10, the connection wiring (50F) and the like formed on the first surface (10F) side and the connection wiring (50B) and the like formed on the second surface (10B) side may extend in the same direction (at the same inclination angle). Conversely, when viewed from the first surface (10F) side of the flexible substrate 10, the connection wiring (50F) and the like formed on the first surface (10F) side and the connection wiring (50B) and the like formed on the second surface (10B) side may extend in intersecting directions (at different inclination angles). Additionally, connection wirings extending in the same direction and connection wirings extending in intersecting directions may be appropriately combined. Angles (inclination angles) at which the connecting wirings extend may all be the same, or some or all of the angles may be different.

Although not illustrated in the drawings, the first surface (10F), the first wirings (30F, 32F, 34F, 130F, 132F, 134F, 230F, 232F, 234F), and the connection wirings (50F, 52F, 54F, 80F, 82F, 84F) are covered with a resin insulating layer. Similarly, the second surface (10B), the second wirings (30B, 32B, 34B, 130B, 132B, 134B, 230B, 232B, 234B), and the connection wirings (50B, 52B, 54B, 80B, 82B, 84B) are covered with a resin insulating layer.

FIG. 8 is a perspective view schematically illustrating a motor coil substrate 550 formed using the coil substrate 2 of the embodiment (FIGS. 1-7). As illustrated in FIG. 8, the motor coil substrate 550 for a motor is formed by winding the coil substrate 2 of the embodiment (FIGS. 1-7) into a cylindrical shape. When the coil substrate 2 is wound into a cylindrical shape, the coil substrate 2 is wound multiple turns around an axis extending in the orthogonal direction (an axis extending parallel to the first side (E1)) with the first side (E1) (FIG. 1) as a starting point. Further, the number of turns the coil substrate is wound is not particularly limited. When the coil substrate 2 is wound into a cylindrical shape, the first surface (10F) of the flexible substrate 10 is positioned on the inner circumferential side, and the second surface (10B) is positioned on the outer circumferential side. When the coil substrate 2 is wound into a cylindrical shape, it is also possible that the first surface (10F) of the flexible substrate 10 is positioned on the outer circumferential side, and the second surface (10B) is positioned on the inner circumferential side. A winding method is determined by specifications of the coil substrate 2, or designs for wiring widths, wiring thicknesses, and the like.

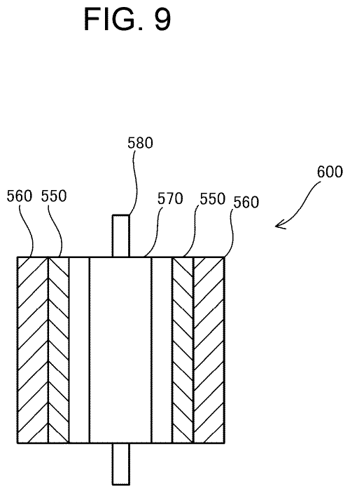

FIG. 9 is a cross-sectional view schematically illustrating a motor 600 formed using the motor coil substrate 550 of the embodiment (FIG. 8). The motor 600 is formed by positioning the motor coil substrate 550 on an inner side of a yoke 560 and positioning a rotation shaft 580 and a magnet 570 fixed to the rotation shaft 580 on an inner side of the motor coil substrate 550.

The structures of the coil substrate 2 (FIGS. 1-7) of the embodiment, the motor coil substrate 550 (FIG. 8), and the motor 600 (FIG. 9) have been described. In the coil substrate 2 of the embodiment, the connection wirings (50F, 52F, 54F) and the like extend obliquely with respect to the longitudinal direction. None of the connection wirings (50F, 52F, 54F) and the like have a portion that extends along the orthogonal direction. The gap (G) (see FIG. 7) between the adjacent connection wirings (50F, 52F) or the like also extends obliquely with respect to the orthogonal direction. The gap (G) is not formed along the orthogonal direction. Therefore, when the coil substrate 2 is wound, bending at a portion of the gap (G) between the connection wirings (50F, 52F) or the like is suppressed. When the motor coil substrate 550 is formed by winding the coil substrate 2 of the embodiment in a circumferential direction, the motor coil substrate 550 can be formed into a cylindrical shape with a circular cross section. When the motor 600 is formed, interference between the magnet 570, which is positioned on the inner side of the motor coil substrate 550, and the motor coil substrate 550 is prevented. Further, since a gap between the motor coil substrate 550 and the yoke 560 becomes constant, high heat dissipation performance is achieved. Therefore, when the motor 600 is formed using the coil substrate 2 of the embodiment, a motor 600 with stable performance can be obtained.

### First Modified Example

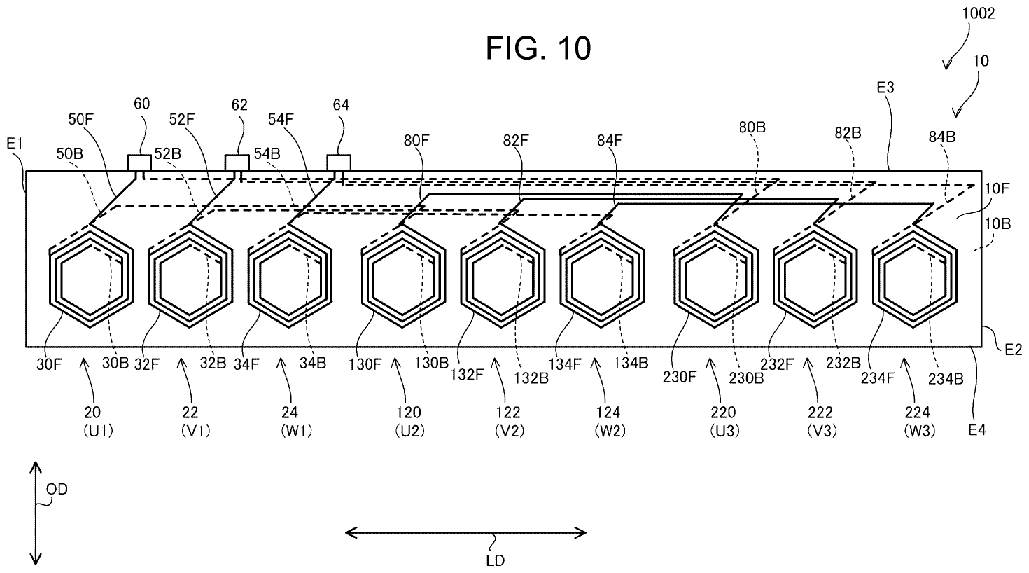

FIG. 10 illustrates a first modified example according to an embodiment of the present invention. FIG. 10 is a plan view illustrating a coil substrate 1002 of the first modified example. In the first modified example, the arrangement of the wirings that form the coils (20, 22, 24, 120, 122, 124, 220, 222, 224) is different from the embodiment.

Also in the first modified example, the coil 20 is formed of a coil-shaped first wiring (30F) provided on the first surface (10F) and a coil-shaped second wiring (30B) provided on the second surface (10B). The first wiring (30F) and the second wiring (30B) are electrically connected via a via conductor 40 penetrating the flexible substrate 10. The first wiring (30F) is formed in a spiral shape (hexagonal spiral shape) from an outer circumference toward an inner circumference. The via conductor 40 is formed at an inner circumferential side end of the first wiring (30F). On the other hand, the second wiring (30B) is formed in a spiral (hexagonal spiral) shape from the inner circumference towards the outer circumference. The via conductor 40 is formed at an outer circumferential side end of the second wiring (30B). As illustrated in FIG. 10, the first wiring (30F) and the second wiring (30B) are formed in spiral shapes wound in the same direction when viewed from the same surface. The first wiring (30F) and the second wiring (30B) are electrically connected in series and function as one coil 20.

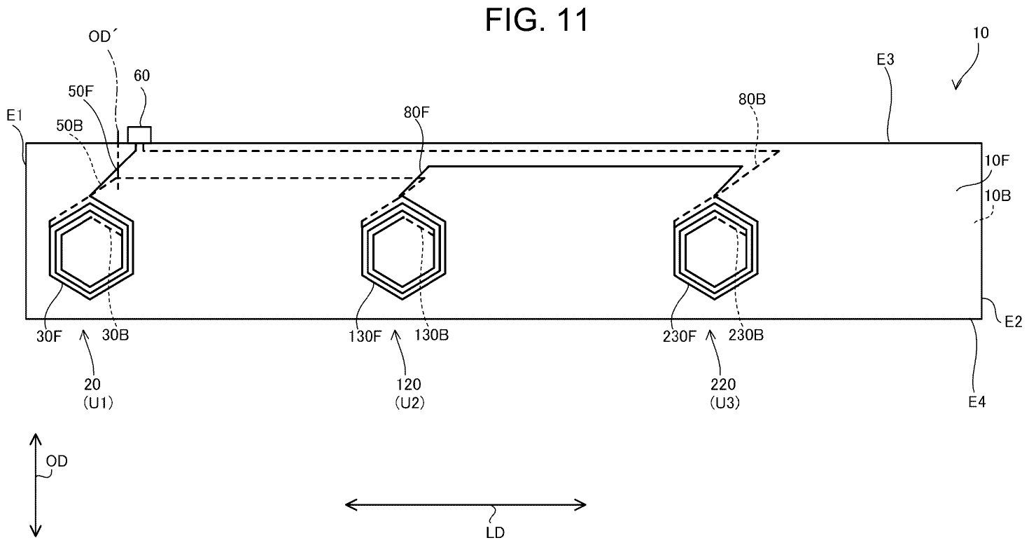

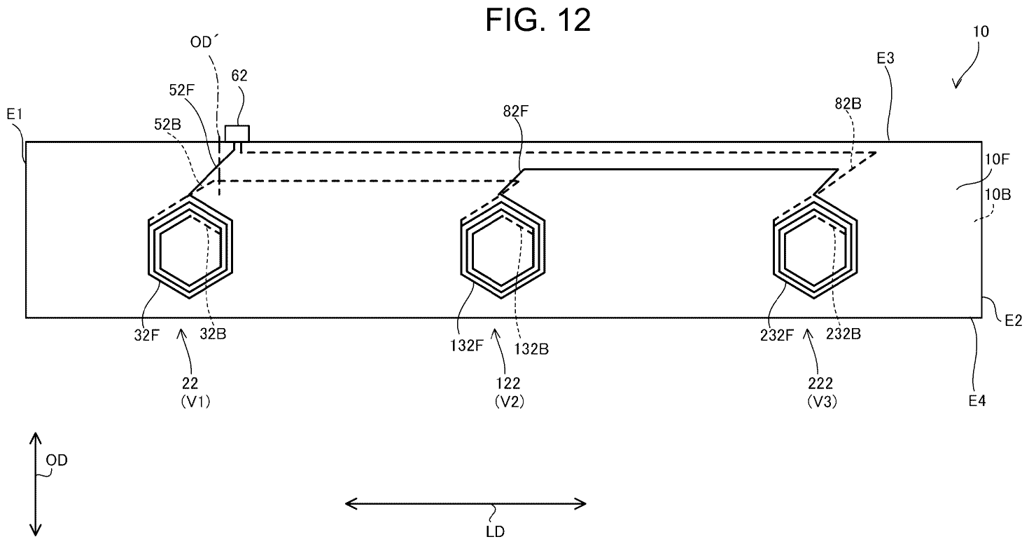

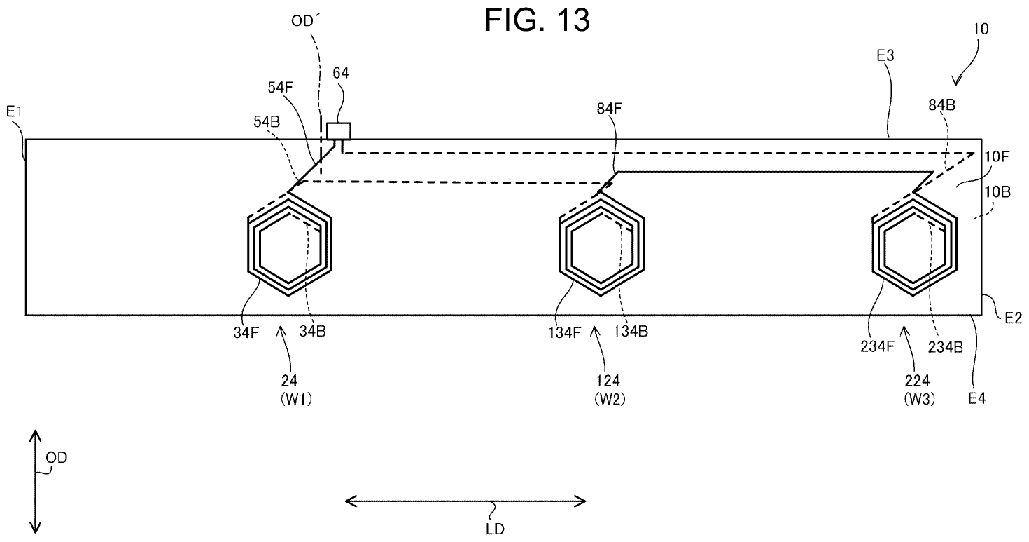

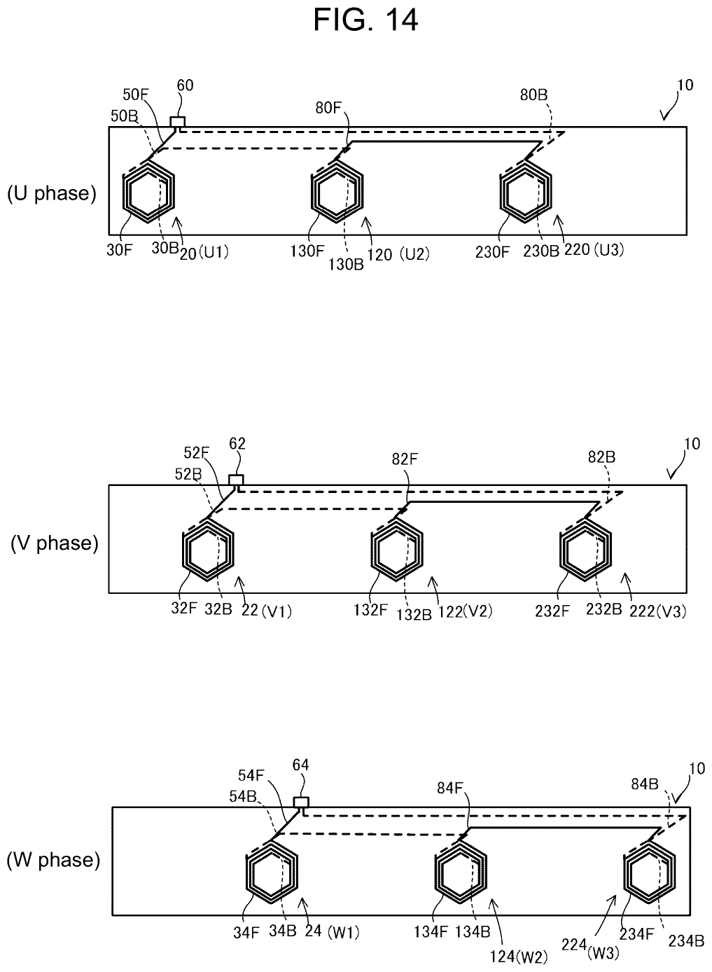

The other coils (22, 24, 120, 122, 124, 220, 222, 224) also have similar structure to the coil 20. As illustrated in FIG. 10, also in the first modified example, the nine coils (20, 22, 24, 120, 122, 124, 220, 222, 224) are formed along the longitudinal direction of the flexible substrate 10. The nine coils (20, 22, 24, 120, 122, 124, 220, 222, 224) are formed in this order from the first side (E1) to the second side (E2). As illustrated in FIGS. 11 and 14, the coils (20, 120, 220) form the U phase. As illustrated in FIGS. 12 and 14, the coils (22, 122, 222) form the V phase. As illustrated in FIGS. 13 and 14, the coils (24, 124, 224) form the W phase. As illustrated in FIG. 14, the U phase, V phase, and W phase are formed offset along the longitudinal direction. The nine coils (20, 22, 24, 120, 122, 124, 220, 222, 224) are formed in the order of the U phase, V phase, and W phase along the longitudinal direction. The U phase, V phase, and W phase of a three-phase motor may be formed in forms other than this.

As illustrated in FIGS. 10-14, also in the first modified example, the connection wirings (50F, 52F, 54F, 80F, 82F, 84F) are formed on the first surface (10F) side. The connection wirings (50B, 52B, 54B, 80B, 82B, 84B) are formed on the second surface (10B) side.

As illustrated in FIGS. 11 and 14, the connection wiring (50F) connects an end part of the first wiring (30F), which is one end of the coil 20, and the terminal 60. The connection wiring (50B) connects an end part of the second wiring (30B), which is the other end of the coil 20, and an end part of the second wiring (130B), which is one end of the coil 120. The connection wiring (80F) connects an end part of the first wiring (130F), which is the other end of the coil 120, and an end part of the first wiring (230F), which is one end of the coil 220. The connection wiring (80B) connects an end part of the second wiring (230B), which is the other end of the coil 220, and the terminal 60. That is, the coils (20, 120, 220) that form the U phase are connected in series via the connection wirings (50F, 50B, 80F, 80B) and the terminal 60.

As illustrated in FIGS. 12 and 14, the connection wiring (52F) connects an end part of the first wiring (32F), which is one end of the coil 22, and the terminal 62. The connection wiring (52B) connects an end part of the second wiring (32B), which is the other end of the coil 22, and an end part of the second wiring (132B), which is one end of the coil 122. The connection wiring (82F) connects an end part of the first wiring (132F), which is the other end of the coil 122, and an end part of the first wiring (232F), which is one end of the coil 222. The connection wiring (82B) connects an end part of the second wiring (232B), which is the other end of the coil 222, and the terminal 62. The coils (22, 122, 222) that form the V phase are connected in series via the connection wirings (52F, 52B, 82F, 82B) and the terminal 62.

As illustrated in FIGS. 13 and 14, the connection wiring (54F) connects an end part of the first wiring (34F), which is one end of the coil 24, and the terminal 64. The connection wiring (54B) connects an end part of the second wiring (34B), which is the other end of the coil 24, and an end part of the second wiring (134B), which is one end of the coil 124. The connection wiring (84F) connects an end part of the first wiring (134F), which is the other end of the coil 124, and an end part of the first wiring (234F), which is one end of the coil 224. The connection wiring (84B) connects an end part of the second wiring (234B), which is the other end of the coil 224, and the terminal 64. The coils (24, 124, 224) that form the W phase are connected in series via the connection wirings (54F, 54B, 84F, 84B) and the terminal 64.

As illustrated in FIGS. 10-14, the connection wirings (50F, 52F, 54F, 80F, 82F, 84F) formed on the first surface (10F) side extend obliquely (are inclined) with respect to the longitudinal direction (the arrow (LD) direction). Substantially none of the connection wirings (50F, 52F, 54F, 80F, 82F, 84F) have a portion that extends in the orthogonal direction (the arrow (OD) direction). The connection wirings (50F, 52F, 54F, 80F, 82F, 84F) extend obliquely (are inclined) also with respect to the orthogonal direction. As illustrated in FIGS. 11-13, the connection wirings (50F, 52F, 54F, 80F, 82F, 84F) are inclined, for example, at +5 degrees or more or −5 degrees or more with respect to a virtual line (OD′) parallel to the orthogonal direction, in terms of an inner angle between the virtual line (OD′) and the connection wirings (50F, 52F, 54F, 80F, 82F, 84F). Further, the connection wirings (50F, 52F, 54F, 80F, 82F, 84F) are desirably inclined at +10 to +45 degrees with respect to the virtual line (OD′) in terms of the inner angle. As a result, a motor coil substrate obtained by winding the coil substrate can be formed into a cylindrical shape with a circular cross section. Further, gaps formed respectively between the connection wiring (50F) and the connection wiring (52F), between the connection wiring (52F) and the connection wiring (54F), between the connection wiring (54F) and the connection wiring (80F), between the connection wiring (80F) and the connection wiring (82F), and between the connection wiring (82F) and the connection wiring (84F) also are inclined with respect to both the longitudinal direction and the orthogonal direction.

As illustrated in FIGS. 10-14, the connection wirings (50B, 52B, 54B, 80B, 82B, 84B) formed on the second surface (10B) side also extend obliquely (are inclined) with respect to the longitudinal direction (the arrow (LD) direction). Also substantially none of the connection wirings (50B, 52B, 54B, 80B, 82B, 84B) have a portion that extends in the orthogonal direction (the arrow (OD) direction). The connection wirings (50B, 52B, 54B, 80B, 82B, 84B) extend obliquely (are inclined) also with respect to the orthogonal direction. In the first modified example, the connection wirings (50B, 52B, 54B, 80B, 82B, 84B) are inclined at +30 degrees with respect to the virtual line (OD′). As illustrated in FIGS. 11-13, the connection wirings (50B, 52B, 54B, 80B, 82B, 84B) also are inclined, for example, at +5 degrees or more or −5 degrees or more with respect to a virtual line (OD′) parallel to the orthogonal direction, in terms of an inner angle between the virtual line (OD′) and the connection wirings (50B, 52B, 54B, 80B, 82B, 84B). Further, the connection wirings (50B, 52B, 54B, 80B, 82B, 84B) are desirably inclined at +10 to +45 degrees with respect to the virtual line (OD′) in terms of the inner angle. As a result, a motor coil substrate obtained by winding the coil substrate can be formed into a cylindrical shape with a circular cross section. Gaps formed respectively between the connection wiring (50B) and the connection wiring (52B), between the connection wiring (52B) and the connection wiring (54B), between the connection wiring (54B) and the connection wiring (80B), between the connection wiring (80B) and the connection wiring (82B), and between the connection wiring (82B) and the connection wiring (84B) also are inclined with respect to both the longitudinal direction and the orthogonal direction.

Also in the first modified example, although not illustrated in the drawings, the first surface (10F), the first wirings (30F, 32F, 34F, 130F, 132F, 134F, 230F, 232F, 234F), and the connection wirings (50F, 52F, 54F, 80F, 82F, 84F) are covered with a resin insulating layer. Similarly, the second surface (10B), the second wirings (30B, 32B, 34B, 130B, 132B, 134B, 230B, 232B, 234B), and the connection wirings (50B, 52B, 54B, 80B, 82B, 84B) are covered with a resin insulating layer.

### Second Modified Example

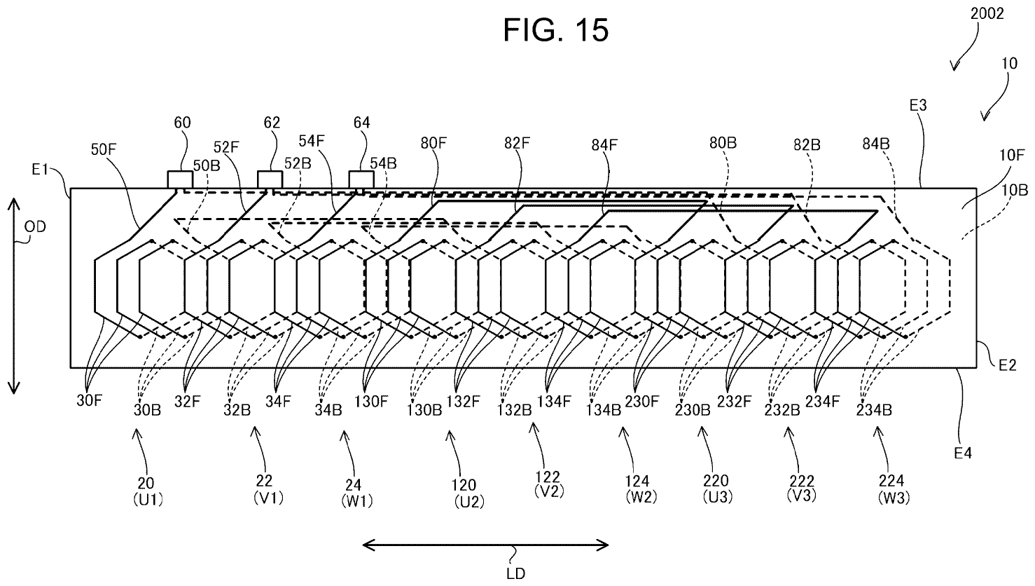

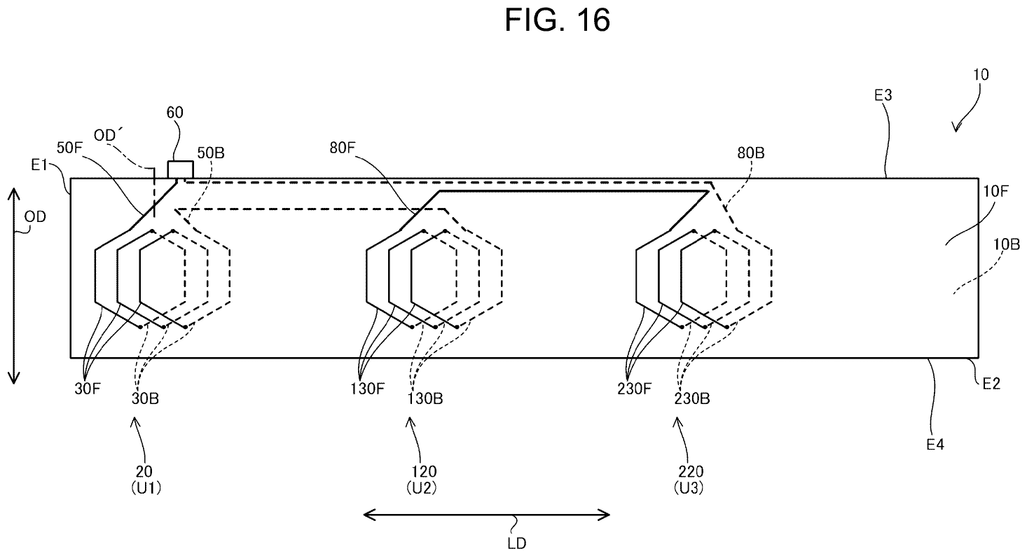

FIG. 15 illustrates a second modified example according to an embodiment of the present invention. FIG. 15 is a plan view illustrating a coil substrate 2002 of the second modified example. In the second modified example, the arrangement of the wirings that form the coils (20, 22, 24, 120, 122, 124, 220, 222, 224) is the same as the embodiment. In the second modified example, the extension direction of the connection wirings (50B, 52B, 54B, 80B, 82B, 84B) on the second surface (10B) side is different from the embodiment. In the second modified example, since the structure other than the extension direction of the connection wirings (50B, 52B, 54B, 80B, 82B, 84B) is the same as the embodiment, a detailed description thereof is omitted.

As illustrated in FIGS. 15-19, also in the second modified example, the connection wirings (50F, 52F, 54F, 80F, 82F, 84F) are formed on the first surface (10F) side. The connection wirings (50B, 52B, 54B, 80B, 82B, 84B) are formed on the second surface (10B) side.

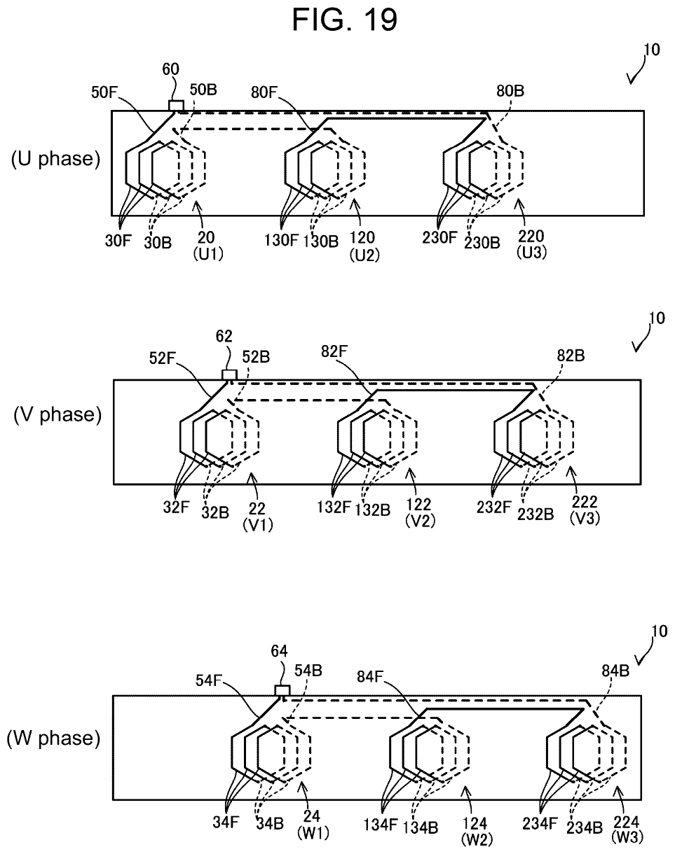

As illustrated in FIGS. 16 and 19, also in the second modified example, the coils (20, 120, 220) that form the U phase are connected in series via the connection wirings (50F, 50B, 80F, 80B) and the terminal 60. However, in the second modified example, when the flexible substrate 10 is viewed from the first surface (10F) side, the connection wiring (50B) extends (at a different inclination angle) in a direction intersecting the connection wiring (50F). Similarly, the connection wiring (80B) also extends (at a different inclination angle) in a direction that intersects the connection wiring (80F).

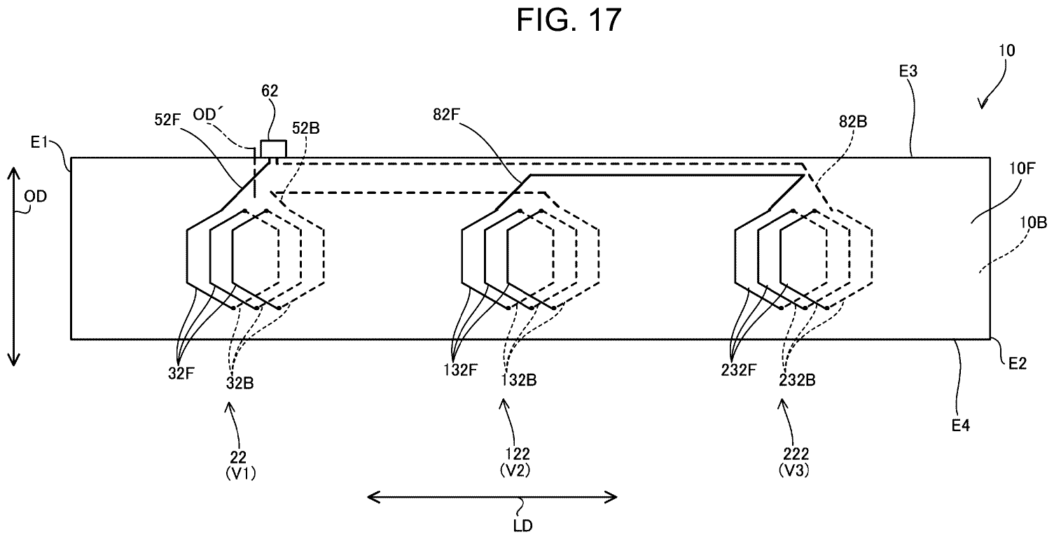

As illustrated in FIGS. 17 and 19, also in the second modified example, the coils (22, 122, 222) that form the V phase are connected in series via the connection wirings (52F, 52B, 82F, 82B) and the terminal 62. However, in the second modified example, when the flexible substrate 10 is viewed from the first surface (10F) side, the connection wiring (52B) extends (at a different inclination angle) in a direction intersecting the connection wiring (52F). Similarly, the connection wiring (82B) also extends (at a different inclination angle) in a direction that intersects the connection wiring (82F). In the second modified example, the connection wirings (50F, 52F, 54F, 80F, 82F, 84F) are inclined at +30 degrees with respect to the virtual line (OD′). The connection wirings (50B, 52B, 54B, 80B, 82B, 84B) are inclined at −30 degrees with respect to the virtual line (OD′).

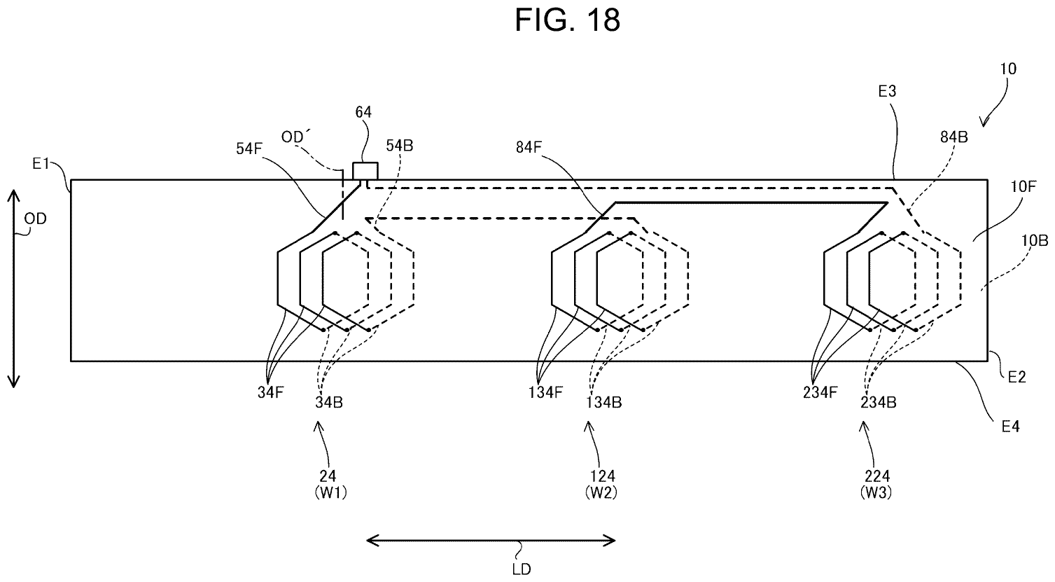

As illustrated in FIGS. 18 and 19, also in the second modified example, the coils (24, 124, 224) that form the W phase are connected in series via the connection wirings (54F, 54B, 84F, 84B) and the terminal 64. However, in the second modified example, when the flexible substrate 10 is viewed from the first surface (10F) side, the connection wiring (54B) extends (at a different inclination angle) in a direction intersecting the connection wiring (54F). Similarly, the connection wiring (84B) also extends (at a different inclination angle) in a direction that intersects the connection wiring (84F).

### Third Modified Example

A structure of a coil substrate of a third modified example is the same as the embodiment. In the third modified example, the connection wirings (50F, 52F) are inclined at +40 degrees with respect to the virtual line (OD′).

### Fourth Modified Example

A structure of a coil substrate of a fourth modified example is the same as the first modified example. In the fourth modified example, the connection wirings (50B, 52B, 54B, 80B, 82B, 84B) are inclined at +40 degrees with respect to the virtual line (OD′).

### Fifth Modified Example

A structure of a coil substrate of a fifth modified example is the same as the second modified example. In the fifth modified example, the connection wirings (50F, 52F, 54F, 80F, 82F, 84F) are inclined at +40 degrees with respect to the virtual line (OD′). The connection wirings (50B, 52B, 54B, 80B, 82B, 84B) are inclined at −40 degrees with respect to the virtual line (OD′).

Japanese Patent Application Laid-Open Publication No. 2021-48718 describes a coil substrate having a flexible substrate and coils formed on the flexible substrate. The coil substrate has connection wirings for connecting the coils and terminals. A cylindrical motor coil substrate is formed by wrapping the coil substrate around a hollow space.

In Japanese Patent Application Laid-Open Publication No. 2021-48718, it is thought that the connection wirings extend in a direction (that is, an orthogonal direction) orthogonal to a direction (that is, a longitudinal direction of the flexible substrate) in which the coil substrate is wound. It is thought that gaps between adjacent connection wirings also are formed along the orthogonal direction. When the coil substrate is wound, it is thought that a force is likely to be applied to a gap portion where no wiring exists, making it likely to bend. As a result, it is thought that the motor coil substrate is formed into a polygonal cylindrical shape with a polygonal cross section, instead of a cylindrical shape with a circular cross section.

When the motor coil substrate has a polygonal cylindrical shape, it is thought that the motor coil substrate may interfere with a magnet positioned on an inner side of the motor coil substrate when a motor is formed. Further, since a gap between the motor coil substrate and a yoke is not constant, it is thought that heat dissipation performance may deteriorate. As a result, it is thought that stable motor performance cannot be achieved.

A coil substrate according to an embodiment of the present invention includes: a flexible substrate that has a first surface and a second surface on the opposite side with respect to the first surface; coils that are each formed by a coil-shaped wiring provided on the first surface and a coil-shaped wiring provided on the second surface; terminals that are formed on one side in a width direction of the flexible substrate; and connection wirings that each connect one of the terminals and a wiring of one of the coils, or each connect wirings of two of the coils. The coil substrate can be formed into a cylindrical shape by being wound along a longitudinal direction of the flexible substrate around an axis extending in an orthogonal direction orthogonal to the longitudinal direction with a reference side on one end side in the longitudinal direction as a starting point. The connection wirings extend obliquely with respect to the longitudinal direction.

In a coil substrate according to an embodiment of the present invention, the connection wirings extend obliquely with respect to the longitudinal direction. Therefore, formation of gaps between adjacent connection wirings along the orthogonal direction is suppressed. When the coil substrate is wound, bending at gap portions between the connection wirings is suppressed. When a motor coil substrate is formed by winding a coil substrate according to an embodiment of the present invention in a circumferential direction, the motor coil substrate can be formed into a cylindrical shape with a circular cross section. Therefore, occurrence of a short circuit between the wirings is suppressed. As a result, when a motor is formed by positioning the motor coil substrate, a magnet, and a yoke in a casing, interference between the magnet, which is positioned on an inner side of the motor coil substrate, and the motor coil substrate is prevented. Further, since a gap between the motor coil substrate and the yoke becomes constant, high heat dissipation performance is achieved. Therefore, when a motor is formed using a coil substrate according to an embodiment of the present invention, a motor with stable performance can be obtained.

In a coil substrate according to an embodiment of the present invention, a gap formed between two adjacent connection wirings may extend obliquely with respect to the longitudinal direction.

In a coil substrate according to an embodiment of the present invention, the connection wirings may include first surface side connection wirings formed on the first surface side and second surface side connection wirings formed on the second surface side. When the flexible substrate is viewed from the first surface side, the first surface side connection wirings and the second surface side connection wirings may respectively extend in intersecting directions.

In a coil substrate according to an embodiment of the present invention, the coils may be each formed by forming first wirings on the first surface side, each forming a half turn of one turn, and forming second wirings on the second surface side, each forming a remaining half turn, with the first wiring and second wiring that form each turn being electrically connected via a via conductor.

In a coil substrate according to an embodiment of the present invention, the connection wirings may be inclined at +5 degrees or more or −5 degrees or more with respect to a virtual line (OD′) parallel to the orthogonal direction.

In a coil substrate according to an embodiment of the present invention, the connection wirings may be inclined at +10 degrees to +45 degrees or −10 degrees to −45 degrees with respect to a virtual line parallel to the orthogonal direction.

A motor coil substrate according to an embodiment of the present invention is formed by winding a coil substrate according to an embodiment of the present invention into a cylindrical shape. The first surface is positioned on an inner peripheral side, and the second surface is positioned on an outer peripheral side.

A motor coil substrate according to an embodiment of the present invention can be formed to have a circular cross section. Therefore, occurrence of a short circuit between the wirings is suppressed. When a motor is formed by positioning the motor coil substrate, a magnet, and a yoke in a casing, interference between the magnet and the motor coil substrate is prevented. High heat dissipation performance is achieved. Therefore, when a motor is formed using a motor coil substrate according to an embodiment of the present invention, a motor with stable performance can be obtained.

A motor according to an embodiment of the present invention is formed by positioning a motor coil substrate according to an embodiment of the present invention on an inner side of a cylindrical yoke and positioning a rotation shaft and a magnet on an inner side of the motor coil substrate.

In a motor according to an embodiment of the present invention, interference between the magnet and the motor coil substrate is prevented. Further, since a gap between the motor coil substrate and the yoke also becomes constant, high heat dissipation performance is achieved. A motor with stable performance can be obtained.

Obviously, numerous modifications and variations of the present invention are possible in light of the above teachings. It is therefore to be understood that within the scope of the appended claims, the invention may be practiced otherwise than as specifically described herein.

1. A coil substrate, comprising:
a flexible substrate;
a plurality of terminals formed on one side of the flexible substrate such that the plurality of terminals is positioned in a longitudinal direction of the flexible substrate;
a plurality of coils each comprising a first wiring formed on a first surface and a second wiring formed on a second surface on an opposite side with respect to the first surface; and
a plurality of connection wirings formed on the flexible substrate such that the plurality of connection wirings includes wirings connecting the terminals and the coils respectively and wirings connecting two of the coils respectively and that the connection wirings extend obliquely with respect to the longitudinal direction of the flexible substrate,
wherein the coil substrate is configured to be wound along the longitudinal direction of the flexible substrate around an axis extending in an orthogonal direction orthogonal to the longitudinal direction such that the coil substrate is formed into a cylindrical shape.

2. The coil substrate according to claim 1, wherein the plurality of connection wirings is formed such that a gap formed between two adjacent connection wirings extends obliquely with respect to the longitudinal direction of the flexible substrate.

3. The coil substrate according to claim 1, wherein the plurality of connection wirings includes a plurality of first surface side connection wirings formed on the first surface side and a plurality of second surface side connection wirings formed on the second surface side such that the first surface side connection wirings and the second surface side connection wirings extend in intersecting directions, respectively.

4. The coil substrate according to claim 1, wherein each of the coils includes a plurality of first wirings formed on the first surface side, a plurality of second wirings formed on the second surface side and a plurality of via conductors formed through the flexible substrate such that each of each the first wirings is forming a half turn and that each of the second wirings is forming a remaining half turn and connected to a respective one of the first wirings via a respective one of the via conductors.

5. The coil substrate according to claim 1, wherein the plurality of connection wirings is formed such that the connection wirings are inclined at +5 degrees or more or −5 degrees or more with respect to a virtual line parallel to the orthogonal direction.

6. The coil substrate according to claim 1, wherein the plurality of connection wirings is formed such that the connection wirings are inclined in a range of at +10 degrees to +45 degrees or in a range of at −10 degrees to −45 degrees with respect to a virtual line parallel to the orthogonal direction.

7. A motor coil substrate, comprising:
the coil substrate of claim 1 wound in the longitudinal direction such that the first surface of the flexible substrate is positioned on an inner surface side of the cylindrical shape and that the second surface of the flexible substrate is positioned on an outer surface side of the cylindrical shape.

8. A motor, comprising:
a cylindrical yoke;
the motor coil substrate of claim 7 positioned on an inner side of the cylindrical yoke;
a magnet positioned on the inner side of the cylindrical yoke such that the magnet is positioned on an inner side of the motor coil substrate; and
a rotation shaft positioned on the inner side of the cylindrical yoke such that the rotation shaft is positioned on an inner side of the magnet.

9. The coil substrate according to claim 2, wherein the plurality of connection wirings includes a plurality of first surface side connection wirings formed on the first surface side and a plurality of second surface side connection wirings formed on the second surface side such that the first surface side connection wirings and the second surface side connection wirings extend in intersecting directions, respectively.

10. The coil substrate according to claim 2, wherein each of the coils includes a plurality of first wirings formed on the first surface side, a plurality of second wirings formed on the second surface side and a plurality of via conductors formed through the flexible substrate such that each of each the first wirings is forming a half turn and that each of the second wirings is forming a remaining half turn and connected to a respective one of the first wirings via a respective one of the via conductors.

11. The coil substrate according to claim 2, wherein the plurality of connection wirings is formed such that the connection wirings are inclined at +5 degrees or more or −5 degrees or more with respect to a virtual line parallel to the orthogonal direction.

12. The coil substrate according to claim 2, wherein the plurality of connection wirings is formed such that the connection wirings are inclined in a range of at +10 degrees to +45 degrees or in a range of at −10 degrees to −45 degrees with respect to a virtual line parallel to the orthogonal direction.

13. The coil substrate according to claim 3, wherein each of the coils includes a plurality of first wirings formed on the first surface side, a plurality of second wirings formed on the second surface side and a plurality of via conductors formed through the flexible substrate such that each of each the first wirings is forming a half turn and that each of the second wirings is forming a remaining half turn and connected to a respective one of the first wirings via a respective one of the via conductors.

14. The coil substrate according to claim 3, wherein the plurality of connection wirings is formed such that the connection wirings are inclined at +5 degrees or more or −5 degrees or more with respect to a virtual line parallel to the orthogonal direction.

15. The coil substrate according to claim 3, wherein the plurality of connection wirings is formed such that the connection wirings are inclined in a range of at +10 degrees to +45 degrees or in a range of at −10 degrees to −45 degrees with respect to a virtual line parallel to the orthogonal direction.

16. The coil substrate according to claim 4, wherein the plurality of connection wirings is formed such that the connection wirings are inclined at +5 degrees or more or −5 degrees or more with respect to a virtual line parallel to the orthogonal direction.

17. The coil substrate according to claim 4, wherein the plurality of connection wirings is formed such that the connection wirings are inclined in a range of at +10 degrees to +45 degrees or in a range of at −10 degrees to −45 degrees with respect to a virtual line parallel to the orthogonal direction.

18. The coil substrate according to claim 9, wherein each of the coils includes a plurality of first wirings formed on the first surface side, a plurality of second wirings formed on the second surface side and a plurality of via conductors formed through the flexible substrate such that each of each the first wirings is forming a half turn and that each of the second wirings is forming a remaining half turn and connected to a respective one of the first wirings via a respective one of the via conductors.

19. The coil substrate according to claim 9, wherein the plurality of connection wirings is formed such that the connection wirings are inclined at +5 degrees or more or −5 degrees or more with respect to a virtual line parallel to the orthogonal direction.

20. The coil substrate according to claim 9, wherein the plurality of connection wirings is formed such that the connection wirings are inclined in a range of at +10 degrees to +45 degrees or in a range of at −10 degrees to −45 degrees with respect to a virtual line parallel to the orthogonal direction.
